(19) United States
(12) Patent Application Publication
(10) Pub. No.: US 2017/0359031 A1
(43) Pub. Date: Dec. 14, 2017

(54) A RADIO FREQUENCY POWER AMPLIFIER

(71) Applicant: LEONARDO MW LTD, Basildon, Essex (GB)

(72) Inventors: Mervin HAYNES, Basildon, Essex (GB); Angus David MCLACHLAN, Basildon, Essex (GB); Steven CRIPPS, Basildon, Essex (GB); Jeffrey POWELL, Basildon, Essex (GB)

(73) Assignee: LEONARDO MW LTD, Basildon, Essex (GB)

(21) Appl. No.: 15/541,239

(22) PCT Filed: Dec. 30, 2015
(86) PCT No.: PCT/EP2015/081431

§ 371 Date: Jun. 30, 2017

(30) Foreign Application Priority Data
Dec. 30, 2014 (GB) 1423350.6

(51) Int. Cl. H03F 1/02; H03F 3/19; H03F 3/21

(52) U.S. Cl. CPC H03F 1/0288; H03F 3/211; H03F 1/0205; H03F 3/19; H03F 2200/204; H03F 2200/451; H03F 2200/192

(57) ABSTRACT

A power amplifier is described that includes a balanced amplifier arrangement having an input quadrant coupler and output quadrant coupler and two amplifiers, which may include or consist of single transistors, there between. The power amplifier also can provide a signal to an isolated port of the output coupler in order to provide impedance matching. This arrangement dispenses with the need for transistor matching networks at the output of the two amplifiers, which in turn enables the power amplifier to be operable over a wider frequency range as compared with a Doherty power amplifier.

The present invention relates to an improved balanced radio frequency power amplifier.

There is a desire for power amplifiers to be highly efficient to reduce the power they consume, which reduces the need for cooling. This is particularly important where the power amplifier is being used in applications with a limited power supply.

Techniques for designing efficient radio frequency power amplifiers (RFPAs) have been widely employed for many decades. Radio systems, however, introduce a more stringent efficiency requirement inasmuch as the efficiency of a conventional RFPA degrades very quickly as the output power is reduced (commonly termed ‘power back-off’ or PBO). This means that an amplitude modulated radio system will have much lower efficiency than the peak efficiency of the RFPA as the modulated transmissions cause low efficiency due to the power amplifier (PA) having low efficiency at the lower points in the modulation cycle.

Several partial solutions to this problem have been proposed, most notably the “Doherty” power amplifier (PA) that is in widespread use in modern mobile communications systems. A Doherty power amplifier comprises a main amplifier and a peaking amplifier, typically being of different operating classes, arranged such that the peaking amplifier operates together with the main amplifier over a defined input power range.

The Doherty PA, however, has limited operational bandwidth and as such is little used in military radar and electronic warfare (EW) systems. This limitation will also pose a problem in the development of new mobile communication systems that require greater bandwidths.

US2005134377 (Dent) describes an amplifier circuit having two amplifying devices run in quadrature and an auxiliary amplifier that generates an artificial reflection signal that is presented to an auxiliary port of the quadcoupler and thus to output ports of the amplifiers. The artificial reflection signal has a phasing offset by 180° from the phase of the output signals from the two amplifiers to provide a resistive load and thus appear to the amplifiers as a load impedance mismatch. The primary amplifiers will have transistor matching networks at their outputs to match the primary amplifiers to the system's impedance. However, because it is difficult to alter the impedance of transistor matching networks, this amplifier circuit will still suffer from limited operational bandwidth.

According to the invention there is provided a radio frequency power amplifier comprising: a balanced amplifier having an input coupler, an output coupler, and two amplifiers each comprising a transistor there-between; the radio frequency power amplifier further comprising means to modify and/or modulate the impedance presented to the output of the two amplifiers by presenting a signal to an isolated port of the output coupler; and further comprising means to modify the phase and/or amplitude of the signal presented to the isolated port of the output coupler to provide impedance matching and/or impedance modulation to tune for transistor parasitic effects.

This arrangement extends the efficiency of the radio frequency power amplifier over a wider input power range compared with a traditional balanced amplifier. Because impedance matching and/or modulation can be performed at the balanced device ports, the amplifiers need not comprise transistor matching networks thereby enabling the power amplifier of the invention to be physically smaller and operate over a wider bandwidth compared with a traditional Doherty PA and the circuit of US2005134377.

It is preferred that the radio frequency power amplifier includes an auxiliary amplifier the output of which is presented to the isolated port of the output coupler.

In a preferred embodiment, the signal presented to the isolated port of the output coupler has substantially the same frequency as a signal presented to the input port of the balanced amplifier but favourably has a prescribed relative phase and amplitude to the said input signal.

It is favourable that an input signal is presented to both the input of the balanced amplifier and the isolated port of the output coupler. This provides a convenient method of providing a signal to the isolated port of the output coupler that has the same characteristics as the signal inputted to the balanced amplifier.

It is preferable that the radio frequency power amplifier comprises means to modify the signal presented to the auxiliary amplifier.

It is preferred that the input coupler and output coupler are quadrature couplers.

The invention will now be described by way of example with reference to the following figures:

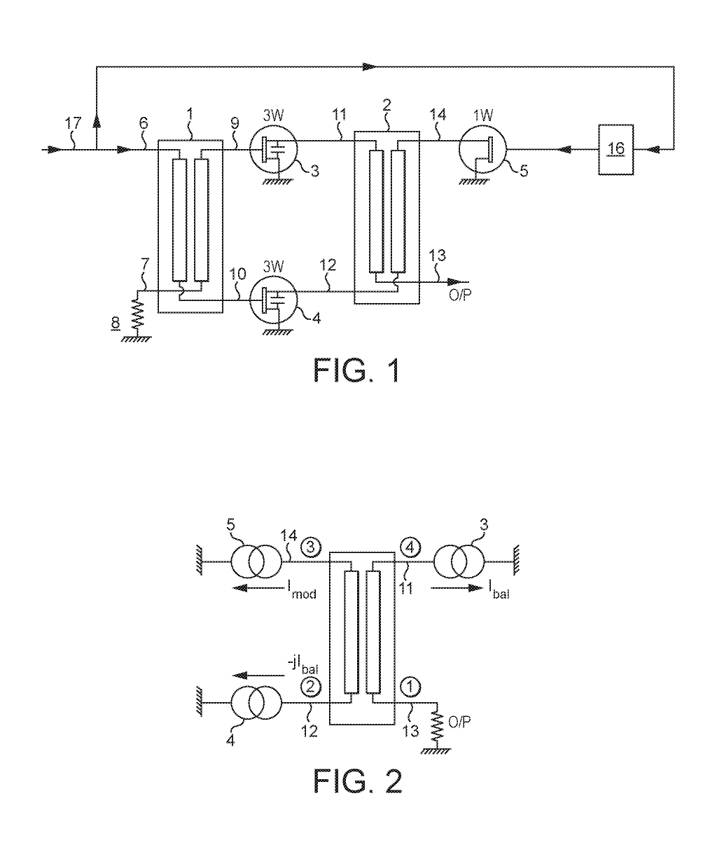

FIG. 1 is a schematic of a load modulated radio frequency balanced amplifier comprising a balanced amplifier having an auxiliary amplifier driving an isolated port of the output coupler; and

FIG. 2 is a circuit analysis schematic of the schematic FIG. 1.

Referring to the FIG. 1 there is shown a balanced amplifier having an input quadrature coupler 1, output quadrature coupler 2, and two 3 W amplifiers 3, 4. In this embodiment the two 3 W amplifiers 3, 4 are single transistors though more complex arrangements and/or different power levels may be used. Also illustrated is an auxiliary 1 W amplifier 5 that is connected to the output quadrature coupler 2 of the balanced amplifier to provide load balancing in a manner to be described.

The input quadrature coupler 1 has an input port 6 for receiving a signal 17 to be amplified, an isolated input port 7 terminated in a matched impedance 8, and two outputs 9, 10. The signals leaving the respective outputs 9, 10 have a ninety degree phase difference. This arrangement provides the benefit that signals reflected by the amplifiers 3,4 towards the input 6 cancel each other out.

The signals from the outputs 9, 10 are fed to the respective amplifiers 3, 4. The outputs of the amplifiers 3,4 are in turn fed to input ports 11, 12 of the output quadrature coupler 2.

The input signal 17 fed to input 6 of the input quadrature coupler 1 is also fed to the auxiliary amplifier 5, optionally via signal modifying means 16 to be described later.

The output of the auxiliary amplifier 5 is presented to isolated port 14 of the output quadrature coupler 2. The description below shows that through this arrangement, the load modulation presented by the auxiliary amplifier 5 to port 14 acts to modulate the impedances presented to the two amplifiers 3,4.

The key properties of the load modulated balance amplifier are demonstrated using the schematic representation shown in FIG. 2. The transistors 3,4,5 of FIG. 1 are represented as current sinks. As is convention, in FIG. 2 the output port 13 is represented as \textcircled{1}, ports 12 and 11 are represented as \textcircled{2} & \textcircled{4} respectively and port 14 is represented as \textcircled{3}.

The properties and actions of the load modulated balance amplifier can be determined by considering the 4-port impedance matrix for a 3 dB quadrature coupler:

$$[ \begin{matrix}{V}_{1} \\ {V}_{2} \\ {V}_{3} \\ {V}_{4}\end{matrix} ] = {Z}_{0} [ \begin{matrix}0 & 0 & - j & - j \sqrt{2} \\ 0 & 0 & - j \sqrt{2} & - j \\ - j & - j \sqrt{2} & 0 & 0 \\ - j \sqrt{2} & - j & 0 & 0\end{matrix} ] [ \begin{matrix}{I}_{1} \\ {I}_{2} \\ {I}_{3} \\ {I}_{4}\end{matrix} ]$$

From this, the impedances at the balanced ports 12\textcircled{2} and 11\textcircled{4} can be shown to be:

$${Z}_{2} = {Z}_{4} = {Z}_{0} ( 1 - \sqrt{2} \frac{{I}_{mod}}{{I}_{bal}} )$$

where I_{bal} is the balanced device current, and I_{mod} is the current supplied by the auxiliary amplifier 5 to port 14\textcircled{3}. Thus as the value of I_{mod} varies, the impedance Z₂ Z₄ presented to respective amplifiers 4,3 by ports 11\textcircled{4} 12\textcircled{2} varies accordingly

By varying the current supplied by the auxiliary amplifier device 5 to port 14 it is possible to modulate I_{mod} so that optimum efficiency is maintained as the power of input signal 17 to port 6 decreases (power back-off).

Using the input signal 17 (modified or otherwise by means 16) to port 6 to control the output of the auxiliary device 5 provides a convenient method to vary the impedance presented to the amplifiers 3,4 to suit variation in the power of the input signal to port 6.

In addition, because there is conservation of energy, the combined powers of the three amplifiers 3,4,5 will appear at the output port 13\textcircled{1}; e.g. in FIG. 1 the final output at port 13\textcircled{1} of the output quadrature coupler will be 7 W, the sum of the three individual powers provided at ports 12\textcircled{2}, 11\textcircled{3}, 14\textcircled{4} of the output quadrature coupler 2.

The system further comprises means 16 for controlling the amplitude and phase of the signal outputted by the auxiliary amplifier 5 to tune for transistor parasitic effects such as output capacitance. In this way it is possible to remove the need for transistor matching networks at the output of amplifiers 3,4. Control of the amplitude and phase of the input signal to the auxiliary amplifier 5 can be done using commonly known apparatus and methods to persons skilled in the art, for example using a variable attenuator and/or a four quadrant phase shifter.

The power of amplifiers 3,4,5 may be varied from those described in relation to FIG. 1 so long as the power of amplifiers 3,4 remains substantially the same. In most applications the power of the auxiliary amplifier 5 will be less than the power of the first and second amplifiers 3,4 though this does not always need to be the case.

It will be appreciated that the load modulated radio frequency balanced power amplifier described above may be applicable for use with signal frequencies not limited to those in the RF and microwave range.

Although it is preferred that the input signal fed to input 6 is also fed to auxiliary amplifier 5 and/or means 16 for controlling the amplitude and phase, in certain applications the signal fed to auxiliary amplifier 5 or means 16 may be generated independently from a different source.

In a variation, the auxiliary amplifier 5 may itself be or comprise a load modulated balanced amplifier in a recursive arrangement.

1. A radio frequency power amplifier comprising:
a balanced amplifier having an input coupler, an output coupler, and two amplifiers each having a transistor, there-between;
means to modify and/or modulate impedance presented to outputs of the two amplifiers by presenting a signal to an isolated port of the output coupler; and
means to modify a phase and/or amplitude of the signal presented to the isolated port of the output coupler to tune for transistor parasitic effects.

2. A radio frequency power amplifier according to claim 1, wherein the signal presented to the isolated port of the output coupler has substantially the same characteristics as a signal presented to an input port of the balanced amplifier.

3. A radio frequency power amplifier according to claim 1, wherein the signal presented to the isolated port of the output coupler has substantially the same frequency as a signal presented to an input port of the balanced amplifier.

4. A radio frequency power amplifier according to claim 1 comprising:
an auxiliary amplifier arranged to present the signal to the isolated port of the output coupler.

5. A radio frequency power amplifier according to claim 2 wherein an input signal is presented to both an input of the balanced amplifier and the isolated port of the output coupler.

6. A radio frequency power amplifier according to claim 12, comprising:
means to modify an input signal to the auxiliary amplifier.

7. A radio frequency power amplifier according to claim 6 comprising:
means to modify a phase and/or amplitude of the light signal to the auxiliary amplifier.

8. A radio frequency power amplifier comprising:
a balanced amplifier having an input coupler, an output coupler, and two amplifiers there-between; and
means to modify and/or modulate impedance presented to an output of the two amplifiers by presenting a signal to an isolated port of the output coupler.

9. A radio frequency power amplifier comprising:
a balanced amplifier having an input coupler, an output coupler, and two amplifiers each having a transistor there-between;
means to modify and/or modulate an impedance presented to outputs of the two amplifiers by presenting a signal to an isolated port of the output coupler; and
means to modify a phase and/or amplitude of the signal presented to the isolated port of the output coupler to provide impedance matching.

10. A radio frequency power amplifier according to claim 2 comprising:
an auxiliary amplifier arranged to present the signal to the isolated port of the output coupler.

11. A radio frequency power amplifier according to claim 4 wherein an input signal is presented to both an input of the balanced amplifier and the isolated port of the output coupler.

12. A radio frequency power amplifier according to claim 3 wherein an input signal is presented to both an input of the balanced amplifier and the isolated port of the output coupler.
